(19) United States
(12) Patent Application Publication
(10) Pub. No.: US 2010/0209610 A1
(43) Pub. Date: Aug. 19, 2010

(54) GROUP IV COMPLEXES AS CVD AND ALD PRECURSORS FOR FORMING METAL-CONTAINING THIN FILMS

(75) Inventors: Thomas M. Cameron, Newtown, CT (US); Chongying Xu, New Milford, CT (US)

Correspondence Address: INTELLECTUAL PROPERTY / TECHNOLOGY LAW, PO BOX 14329, RESEARCH TRIANGLE PARK, NC, 27709, US

(73) Assignee: ADVANCED TECHNOLOGY MATERIALS, INC., Danbury, CT (US)

(21) Appl. No.: 12/669,184

(22) PCT Filed: Jul. 16, 2008
(86) PCT No.: PCT/US08/70233

§ 371 Date: Feb. 9, 2010

Related U.S. Application Data
(60) Provisional application No. 60/949,901, filed on Jul. 16, 2007.

(51) Int. Cl. C23C 16/22; C07F 7/28; C07F 7/00; C23C 16/44; C23C 16/40; C23C 16/34; C23C 16/42; C23C 16/30

(52) U.S. Cl. 427/255.28; 556/51; 427/248.1; 106/287.19

(57) ABSTRACT

A metal precursor, selected from among: (i) precursors of the formula (NR¹R²)₄₋ₓM(chelate)ₓ, and (ii) precursors of the formula (NR¹⁰R¹¹)_{4-2y}M(¹²RN(CH₂)_{z}NR¹³)_{y}, wherein: x=1, 2, 3, or 4; M=Ti, Zr, or Hf; each chelate is independently selected from among guanidinate, amidinate, and isoureate ligands of specific formula; y is 0, 1, or 2; and each of R¹, R², R¹⁰, R¹¹, R¹² and R¹³ is independently selected from among H, C₁-C₁₂ alkyl, C₁-C₁₂ alkylamino, C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl, perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of the precursor can be C₁-C₄ alkylene, silylene (—SiH₂—), or C₁-C₄ dialkylsilylene. Such precursors have utility for forming Ti-, Zr- and/or Hf-containing films on substrates, in the manufacture of microelectronic devices or structures.

### FIELD OF THE INVENTION

The present invention relates to Group IV guanidinate, amidinate and isoureate complexes having utility for forming metal films on substrates such as wafers or other microelectronic device substrates, as well as associated processes of making and using such complexes, and source packages of such complexes.

### DESCRIPTION OF THE RELATED ART

A variety of precursors are in use for forming Group IV metal-containing films in the manufacture of microelectronic devices and structures, including precursors for zirconium, hafnium and titanium.

One currently used precursor for deposition of zirconium-containing high k dielectric thin films is tetrakis(ethylmethylamido)zirconium IV. This precursor, however, is a non-optimal material for deposition of films because of high carbon incorporation during film growth at lower temperatures. Higher temperature film growth, while overcoming the carbon incorporation problem, entails a problem of low conformality of the deposited film. In addition, tetrakis(ethylmethylamido)zirconium IV is very air sensitive and difficult to handle, leading to particle generation during film deposition.

These problems variously affect other Group IV precursors. It would therefore be a significant advance in the art to provide new precursors for zirconium, hafnium and titanium are desired, which are characterized by superior stability and conformality, and low carbon content, and which are able to be deposited efficiently in chemical vapor deposition and atomic layer deposition processes.

### SUMMARY OF THE INVENTION

The present invention relates to Group IV zirconium, hafnium and titanium precursors useful in chemical vapor deposition and atomic layer deposition applications, to form corresponding metal-containing films on substrates, as well as associated processes and packaged forms of such precursors.

In one aspect, the invention relates to a metal precursor, selected from among:

(i) precursors of the formula

(NR¹R²)₄₋ₓM(chelate)ₓ

wherein:
x=1, 2, 3, or 4;

### M=Ti, Zr, or Hf;

each chelate is independently selected from among guanidinate, amidinate, and isoureate, of the formula

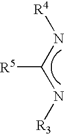

wherein R⁵═NR⁶R⁷ for guanidinates, R⁵═R⁸ for amidinate, R⁵═OR⁹ for isoureate,
each of R¹, R², R³, R⁴, R⁶, R⁷, R⁸ and R⁹ is independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₂-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene;
and when x=1, and chelate=guanidinate, all nitrogen substituents≠alkyl; and
(ii) precursors of the formula

(NR¹⁰R¹¹)_{4-2y}M(¹²RN(CH₂)_{z}NR¹³)_{y}:

wherein:
y is 0, 1, or 2;

### M=Ti, Zr, or Hf;

each of R¹⁰, R¹¹, R¹² and R¹³ is independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene; and
z is an integer of at least 1.

In another aspect, the invention relates to a metal precursor of the formula

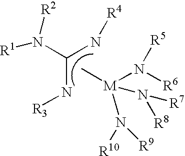

wherein:

### M=Ti, Zr, or Hf;

each of R¹-R¹⁰ is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene, and
all R¹-R¹⁰ are not all simultaneously alkyl.

A further aspect of the invention relates to a method of making a metal precursor of a type broadly described above, wherein when the metal precursor comprises a guanidinate precursor, page method comprises:

reacting (i) a guanidine compound of the formula

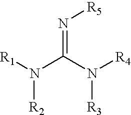

wherein each of each of R¹-R⁵ is independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene, with the proviso that at least one of R¹-R⁵ is H, with (ii) a metal amide compound of the formula

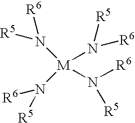

wherein each R⁵ and R⁶ is independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene, and

### M=Ti, Zr, or Hf;

wherein when said metal precursor comprises an amidinate precursor, a corresponding alkene compound of (i) is used in said reacting, and
wherein when said metal precursor comprises an isoureate precursor, a corresponding ether or alkoxide compound of (i) is used in said reacting.

A further aspect of the invention relates to a method of forming a Group IV metal-containing film on a substrate, comprising use of a precursor composition of the invention.

In another aspect, the invention relates to a guanidinate having the formula (1):

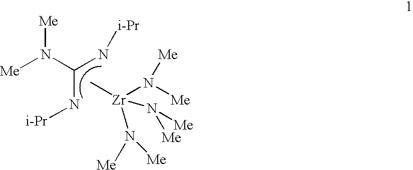

wherein Me is methyl and i-Pr is isopropyl.

Another aspect of the invention relates to a metal complex including a metal selected from among zirconium, hafnium and titanium, wherein said metal constitutes a central atom having coordinated thereto at least one amide ligand, with remaining non-amide ligands being independently selected from among guanidinate, amidinate and isoureate ligands.

A further aspect of the invention relates to a metal precursor selected from among precursors of formulae (5) and (6):

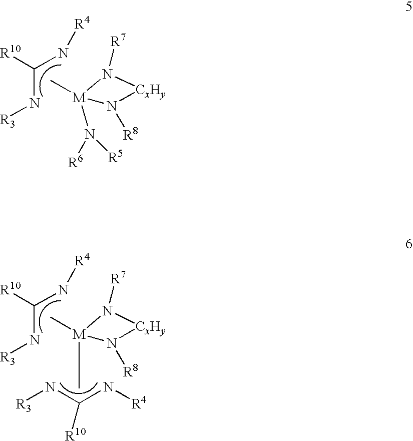

wherein:
R³-R¹⁰ are each independently selected from among is independently selected from among H, C₁-C₁₂ alkyl, C₁-C₁₂ alkylamino, C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl, perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene;

### M is Zr, Hf or Ti; and

CₓH_{y} is a moiety in which x and y are integers that may be varied in relation to one another and are selected from among saturated divalent groups and unsaturated divalent groups.

An additional aspect of the invention relates to a precursor composition comprising at least one metal precursor of the invention, and a solvent for the metal precursor(s).

In another aspect, the invention relates to a precursor vapor of a metal precursor as described herein.

A still further aspect of the invention relates to a source of a Group IV metal precursor, comprising a storage and dispensing vessel containing a Group IV metal precursor of the invention.

Other aspects, features and embodiments of the invention will be more fully apparent from the ensuing disclosure and appended claims.

### BRIEF DESCRIPTION OF THE DRAWINGS

FIG. 1 is a schematic representation of a material storage and dispensing package containing a zirconium, hafnium or titanium precursor, according to one embodiment of the present invention.

### DETAILED DESCRIPTION OF THE INVENTION, AND PREFERRED EMBODIMENTS THEREOF

The present invention relates to Group IV zirconium, hafnium and titanium metal precursors, characterized by superior stability, and utility for forming highly conformal films with low carbon content. The superior air stability of such precursors also enables fewer particles to be generated in the CVD/ALD process, than previously used precursors such as tetrakis(ethylmethylamido)zirconium IV.

Metal precursors of the invention include those selected from among:

(i) precursors of the formula

(NR¹R²)₄₋ₓM(chelate)ₓ

wherein:
x=1, 2, 3, or 4;

### M=Ti, Zr, or Hf;

each chelate is independently selected from among guanidinate, amidinate, and isoureate, of the formula

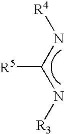

wherein R⁵═NR⁶R⁷ for guanidinates, R⁵═R⁸ for amidinate, R⁵═OR⁹ for isoureate,
each of R¹, R², R³, R⁴, R⁶, R⁷, R⁸ and R⁹ is independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene;
and when x=1, and chelate=guanidinate, all nitrogen substituents #alkyl;
and
(ii) precursors of the formula

(NR¹⁰R¹¹)_{4-2y}M(¹²RN(CH₂)_{z}NR¹³)_{y}:

wherein:
y is 0, 1, or 2;

### M=Ti, Zr, or Hf;

each of R¹⁰, R¹¹, R¹² and R¹³ is independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene; and
z is an integer of at least 1.

One class of metal precursors of the invention include guanidinates of the formula

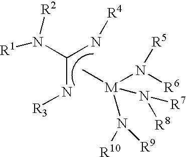

wherein:

### M=Ti, Zr, or Hf;

each of R¹-R¹⁰ is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene, and
all R¹-R¹⁰ are not all simultaneously alkyl.

Other classes of precursors of the invention include amidinates of the above formulae. Another class of precursors of the invention include isoureates of the above formulae.

The guanidinates of the invention may be made, in a synthesis constituting one aspect of the invention, by reacting (i) a guanidine compound of the formula

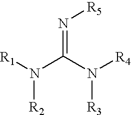

wherein each of each of R¹-R⁵ is independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene, with the proviso that at least one of R¹-R⁵ is H, with (ii) a metal amide compound of the formula

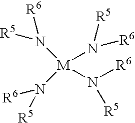

wherein each R⁵ and R⁶ is independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene, and

### M=Ti, Zr, or Hf.

Amidinates and isoureates of the invention can be formed by corresponding syntheses, in which the guanidine reactant is replaced by reactants in which the ═NR₅ moiety of the guanidine is replaced with alkenyl, alkoxy, ether or other suitable moieties.

The precursors of the invention are useful for forming Group IV metal-containing films on substrates. As described more fully hereinafter, the precursors of the invention can be supplied in a packaged form, to provide a ready source of the precursor for film formation processes.

In one aspect of the invention, Group IV metal complexes of titanium, zirconium or hafnium are used as precursors for the CVD or ALD deposition of thin films of metals or metal containing oxides, nitrides, oxynitrides, silicates, silicides, and/or other metal-containing materials.

One illustrative guanidinate of the invention is a zirconium monoguanidinate(triamide) having the formula (1):

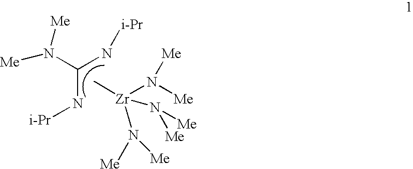

wherein Me is methyl and i-Pr is isopropyl.

Additional complexes of the invention include those corresponding to formula (1), but wherein Zr is replaced with Ti (formula (2)) or with Hf (formula (3)), or in which one or more of the amide groups is replaced by guanidinyl, or alternatively amidinate or isoureate functionality (formulae (4)).

The invention in one embodiment therefore contemplates Zr, Hf and Ti complexes whose ligands coordinated to the central metal atom include at least one amide ligand and with remaining non-amide ligands being independently selected from among guanidinate, amidinate and isoureate ligands. As one example, the complex may have two amide ligands, a guanidinate ligand and an amidinate ligand.

Another class of compounds of the invention include those of the formulae (5) and (6):

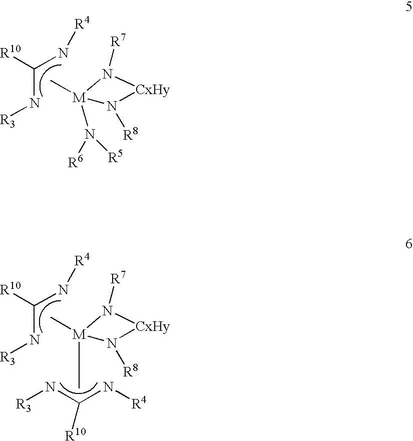

wherein:
R³-R¹⁰ are each independently selected from among is independently selected from among H, C₁-C₁₂ alkyl, C₁-C₁₂ alkylamino (including monoalkylamino as well as dialkylamino substituent species in such term), C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl (e.g., C₃-C₆ alkylsilyl), perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene;

### M is Zr, Hf or Ti; and

CₓH_{y} is a moiety in which x and y are integers that may be varied in relation to one another to include saturated divalent groups as well as unsaturated divalent groups, such as alkylene wherein x is 1 and y is 2, e.g., (—CH₂—)ₙ wherein n is an integer having a value of from 1 to 6, and alkenylene, e.g., —CH═CH—, —CH═CH—CH₂—, etc.

Such complexes (5) and (6) may be formed by synthetic reaction schemes such as those shown below.

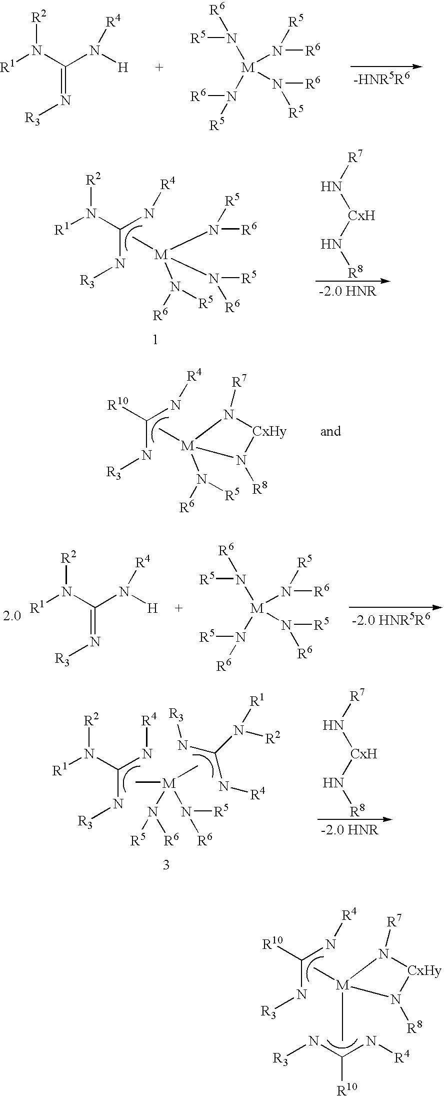

The Group IV precursor complexes of the invention can be supplied in any suitable form for volatilization to produce the precursor vapor for deposition contacting with the substrate, e.g., in a liquid form that is vaporized or as a solid that is dissolved or suspended in a solvent medium for flash vaporization, as a sublimable solid, or as a solid having sufficient vapor pressure to render it suitable for vapor delivery to the deposition chamber, or in any other suitable form.

When solvents are employed for delivery of the precursors of the invention, any suitable solvent media can be employed in which the precursor can be dissolved or dispersed for delivery. By way of example, the solvent medium may be a single-component solvent or a multicomponent solvent mixture, including solvent species such as C₃-C₁₂ alkanes, C₂-C₁₂ ethers, C₆-C₁₂ aromatics, C₇-C₁₆ arylalkanes, C₁₀-C₂₅ arylcyloalkanes, and further alkyl-substituted forms of aromatic, arylalkane and arylcyloalkane species, wherein the further alkyl substituents in the case of multiple alkyl substituents may be the same as or different from one another and wherein each is independently selected from C₁-C₈ alkyl. Illustrative solvents include amines, ethers, aromatic solvents, glymes, tetraglymes, alkanes, alkyl-substituted benzene compounds, benzocyclohexane (tetralin), alkyl-substituted benzocyclohexane and ethers, with tetrahydrofuran, xylene, 1,4-tertbutyltoluene, 1,3-diisopropylbenzene, dimethyltetralin, octane and decane being potentially useful solvent species in specific applications.

In instances where liquid delivery is employed in deposition processes of the invention to form deposited metal films, it may be preferable to utilize high boiling point solvents in order to avoid metal precursor deposits in the delivery system, such as in flow circuitry, and in vaporizers that are utilized to volatilize the metal precursor to form a corresponding precursor vapor, where the system is otherwise susceptible to solids deposition and clogging.

Accordingly, in various embodiments of the invention, it may be desirable to utilize high boiling aromatic solvents, e.g., aromatic solvents having a boiling point at 1 atmosphere pressure in a range of from about 140° C. to about 250° C. For example, in liquid delivery precursor applications for atomic layer deposition processes, suitable solvents may include xylene, 1,4-tertbutyltoluene, 1,3-diisopropylbenzene, tetralin, dimethyltetralin and other alkyl-substituted aromatic solvents. The solvent medium may also comprise a stabilizing solvent, e.g., a Lewis-base ligand.

In other applications, preferred solvents may include amine solvents, neutral amines such as DMAPA, octane or other aliphatic solvents, aromatic solvents such as toluene, ethers such as tetrahydrofuran (THF), and tetraglymes.

Thus, the precursors may be supplied in liquid delivery systems as individual precursors or mixtures of precursors, in solvent media that may be comprised of a single component solvent, or alternatively may be constituted by a solvent mixture, as appropriate in a given application. The solvents that may be employed for such purpose can be of any suitable type in which the specific precursor(s) can be dissolved or suspended, and subsequently volatilized to form the precursor vapor for contacting with the substrate on which the metal is to be deposited.

In general, the precursor compositions of the invention may alternatively comprise, consist, or consist essentially of any of the components and functional moieties disclosed herein, in specific embodiments of the invention.

Precursor complexes of the invention can be utilized in combinations, in which two or more of such precursors are mixed with one another, e.g., in a solution as a precursor cocktail composition for liquid delivery.

Alternatively, the precursor species may be individually dissolved in solvent(s) and delivered into vaporizers for volatilization of the precursor solution to form a precursor vapor that then is transported to the deposition chamber of the deposition system to deposit the metal-containing film on a wafer or other microelectronic device substrate.

As a still further alternative, the precursors can be delivered by solid delivery techniques, in which the solid is volatilized to form the precursor vapor that then is transported to the deposition chamber, and with the solid precursor in the first instance being supplied in a packaged form for use, e.g., in a ProE-Vap package (ATMI, Inc., Danbury, Conn., USA).

The precursors of the present invention are usefully employed for forming metal-containing thin films of high conformality and uniformity characteristics, by ALD and CVD processes. The process conditions for the deposition process in a specific application may be readily determined empirically by variation of specific conditions (temperature, pressure, flow rate, concentration, etc.) and characterization of the resulting film deposit.

In the formation of metal-containing films, any suitable co-reactant or carrier species may be employed, e.g., oxidants, producing agents, inert gases, etc. In a specific embodiment in which an oxidant is used, the oxidant employed in the deposition may be of any suitable type, e.g., nitrous oxide, oxygen, ozone, water, alcohols, or other suitable oxidant. The co-reactants may be supplied simultaneously, e.g., with the precursors entering the deposition chamber concurrently, in a chemical vapor deposition mode, or separately from the precursors, in an atomic layer deposition or digital CVD mode. The precursors can be employed in an ALD mode, in which a purge pulse separates them from the co-reactants, and matched or unmatched precursors may be used.

In one embodiment of the above-described process, the oxidant is selected from among oxygen, ozone and oxygen plasma. The use of such oxidant may eliminate the need for a final annealing step, such as rapid thermal annealing.

In general, the thicknesses of the Group IV metal-containing layers in the practice of the present invention can be of any suitable value. In a specific embodiment of the invention, the thickness of the Group IV metal-containing layer can be in a range of from 5 nm to 500 nm or more.

As used herein, the term “film” refers to a layer of deposited material having a thickness below 1000 micrometers, e.g., from such value down to atomic monolayer thickness values. In various embodiments, film thicknesses of deposited material layers in the practice of the invention may for example be below 100, 10, or 1 micrometers, or in various thin film regimes below 200, 100, or 50 nanometers, depending on the specific application involved. As used herein, the term “thin film” means a layer of a material having a thickness below 1 micrometer.

As used herein, the singular forms “a”, “and”, and “the” include plural referents unless the context clearly dictates otherwise.

As used herein, the identification of a carbon number range, e.g., in C₁-C₁₂ alkyl, is intended to include each of the component carbon number moieties within such range, so that each intervening carbon number and any other stated or intervening carbon number value in that stated range, is encompassed, it being further understood that sub-ranges of carbon number within specified carbon number ranges may independently be included in smaller carbon number ranges, within the scope of the invention, and that ranges of carbon numbers specifically excluding a carbon number or numbers are included in the invention, and sub-ranges excluding either or both of carbon number limits of specified ranges are also included in the invention. Accordingly, C₁-C₁₂ alkyl is intended to include methyl, ethyl, propyl, butyl, pentyl, hexyl, heptyl, octyl, nonyl, decyl, undecyl and dodecyl, including straight chain as well as branched groups of such types. It therefore is to be appreciated that identification of a carbon number range, e.g., C₁-C₁₂, as broadly applicable to a substituent moiety, enables, in specific embodiments of the invention, the carbon number range to be further restricted, as a sub-group of moieties having a carbon number range within the broader specification of the substituent moiety. By way of example, the carbon number range e.g., C₁-C₁₂ alkyl, may be more restrictively specified, in particular embodiments of the invention, to encompass sub-ranges such as C₁-C₄ alkyl, C₂-C₈ alkyl, C₂-C₄ alkyl, C₃-C₅ alkyl, or any other sub-range within the broad carbon number range.

The precursors of the invention may be further specified in specific embodiments by provisos or limitations excluding specific substituents, groups, moieties or structures, in relation to various specifications and exemplifications thereof set forth herein. Thus, the invention contemplates restrictively defined compositions, e.g., a composition wherein Rⁱ is C₁-C₁₂ alkyl, with the proviso that Rⁱ≠C₄ alkyl when Rⁱ is silyl.

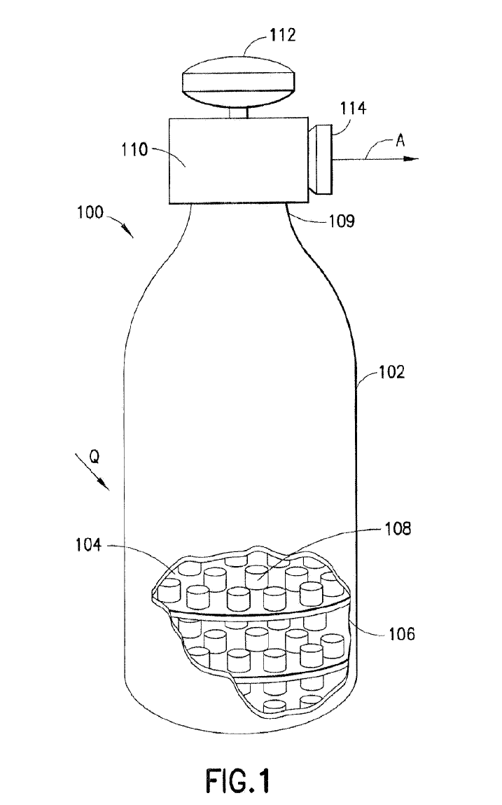

FIG. 1 is a schematic representation of a material storage and dispensing package 100 containing a Group IV zirconium, hafnium or titanium precursor, according to one embodiment of the present invention.

The material storage and dispensing package 100 includes a vessel 102 that may for example be of generally cylindrical shape as illustrated, defining an interior volume 104 therein. In this specific embodiment, the Group IV precursor is a solid at ambient temperature conditions, and such precursor may be supported on surfaces of the trays 106 disposed in the interior volume 104 of the vessel, with the trays having flow passage conduits 108 associated therewith, for flow of vapor upwardly in the vessel to the valve head assembly, for dispensing in use of the vessel.

The solid precursor can be coated on interior surfaces in the interior volume of the vessel, e.g., on the surfaces of the trays 106 and conduits 108. Such coating may be effected by introduction of the precursor into the vessel in a vapor form from which the solid precursor is condensed in a film on the surfaces in the vessel. Alternatively, the precursor solid may be dissolved or suspended in a solvent medium and deposited on surfaces in the interior volume of the vessel by solvent evaporation. In yet another method the precursor may be melted and poured onto the surfaces in the interior volume of the vessel. For such purpose, the vessel may contain substrate articles or elements that provide additional surface area in the vessel for support of the precursor film thereon.

As a still further alternative, the solid precursor may be provided in granular or finely divided form, which is poured into the vessel to be retained on the top supporting surfaces of the respective trays 106 therein.

The vessel 102 has a neck portion 109 to which is joined the valve head assembly 110. The valve head assembly is equipped with a hand wheel 112 in the embodiment shown. The valve head assembly 110 includes a dispensing port 114, which may be configured for coupling to a fitting or connection element to join flow circuitry to the vessel. Such flow circuitry is schematically represented by arrow A in FIG. 1, and the flow circuitry may be coupled to a downstream ALD or chemical vapor deposition chamber (not shown in FIG. 1).

In use, the vessel 102 is heated, such input of heat being schematically shown by the reference arrow Q, so that solid precursor in the vessel is at least partially volatilized to provide precursor vapor. The precursor vapor is discharged from the vessel through the valve passages in the valve head assembly 110 when the hand wheel 112 is translated to an open valve position, whereupon vapor deriving from the precursor is dispensed into the flow circuitry schematically indicated by arrow A.

In lieu of solid delivery of the precursor, the precursor may be provided in a solvent medium, forming a solution or suspension. Such precursor-containing solvent composition then may be delivered by liquid delivery and flash vaporized to produce a precursor vapor. The precursor vapor is contacted with a substrate under deposition conditions, to deposit the metal on the substrate as a film thereon.

In one embodiment, the precursor is dissolved in an ionic liquid medium, from which precursor vapor is withdrawn from the ionic liquid solution under dispensing conditions.

As a still further alternative, the precursor may be stored in an adsorbed state on a suitable solid-phase physical adsorbent storage medium in the interior volume of the vessel. In use, the precursor vapor is dispensed from the vessel under dispensing conditions involving desorption of the adsorbed precursor from the solid-phase physical adsorbent storage medium.

Supply vessels for precursor delivery may be of widely varying type, and may employ vessels such as those commercially available from ATMI, Inc. (Danbury, Conn.) under the trademarks SDS, SAGE, VAC, VACSorb, and ProE-Vap, as may be appropriate in a given storage and dispensing application for a particular precursor of the invention.

The precursors of the invention thus may be employed to form precursor vapor for contacting with a substrate to deposit a thin film of zirconium, hafnium or titanium thereon.

In a preferred aspect, the invention utilizes the Group IV precursors to conduct atomic layer deposition, yielding ALD films of superior conformality that are uniformly coated on the substrate with high step coverage and conformality even on high aspect ratio structures.

Accordingly, the Group IV precursors of the present invention enable a wide variety of microelectronic devices, e.g., semiconductor products, flat panel displays, etc., to be fabricated with zirconium-, hafnium, and/or titanium-containing films of superior quality.

While the invention has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

1. A metal precursor selected from among:
(i) precursors of the formula
(NR¹R²)₄₋ₓM(chelate)ₓ
wherein:
x=1, 2, 3, or 4;
M=Ti, Zr, or Hf;
each chelate is independently selected from among guanidinate, amidinate, and isoureate, of the formula 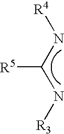
wherein R⁵═NR⁶R⁷ for guanidinates, R⁵═R⁸ for amidinate, R⁵═OR⁹ for isoureate,
each of R¹, R², R³, R⁴, R⁶, R⁷, R⁸ and R⁹ is independently selected from among H, C₁-C₁₂ alkyl, C₁-Cᵤ alkylamino, C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl, perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene;
and when x=1, and chelate=guanidinate, all nitrogen substituents≠alkyl.

2-9. (canceled)

10. The metal precursor of claim 1, comprising a guanidinate of the formula: 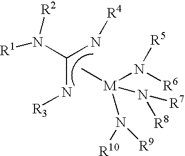
wherein:
M=Ti, Zr, or Hf;
each of R¹-R¹⁰ is independently selected from among H, C₁-C₁₂ alkyl, C₁-C₁₂ alkylamino, C₁-C₁₂ alkoxy, C₃-C₁₀ cycloalkyl, C₂-C₁₂ alkenyl, C₇-C₁₂ aralkyl, C₇-C₁₂ alkylaryl, C₆-C₁₂ aryl, C₅-C₁₂ heteroaryl, C₁-C₁₀ perfluoroalkyl, and silicon-containing groups selected from the group consisting of silyl, alkylsilyl, perfluoroalkylsilyl, triarylsilyl and alkylsilylsilyl, aminoalkyl, alkoxyalkyl, aryloxyalkyl, imidoalkyl, acetylalkyl, and N-bonded functionality between two different nitrogen atoms of said precursor can comprise C₁-C₄ alkylene, silylene (—SiH₂—), or C₁-C₄ dialkylsilylene, and
all R¹-R¹⁰ are not all simultaneously alkyl.

11. The metal precursor of claim 1, comprising at least one guanidinate ligand.

12. (canceled)

13. (canceled)

14. The metal precursor of claim 1, wherein M is zirconium.

15. The metal precursor of claim 1, wherein M is hafnium.

16. The metal precursor of claim 1, wherein M is titanium.

17-20. (canceled)

21. A method of forming a metal-containing film on a substrate, wherein said metal comprises a metal species selected from among zirconium, hafnium and titanium, said method comprising volatilizing a metal precursor according to claim 1, to form a precursor vapor, and contacting said precursor vapor with a substrate to form of said metal-containing film thereon.

22-29. (canceled)

30. The method of claim 21, wherein said contacting is conducted in a chemical vapor deposition process.

31. The method of claim 21, wherein said contacting is conducted in an atomic layer deposition process.

32. The method of claim 21, wherein said metal-containing film comprises a metal compound selected from among metal oxides, metal nitrides, metal oxynitrides, metal silicates, and metal silicides.

33. The method of claim 32, wherein said metal comprises zirconium.

34. The method of claim 32, wherein said metal comprises hafnium.

35. The method of claim 32, wherein said metal comprises titanium.

36. A guanidinate having the formula (1): 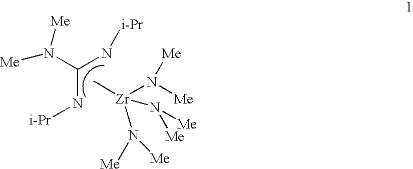
wherein Me is methyl and i-Pr is isopropyl.

37. A metal complex including a metal selected from among zirconium, hafnium and titanium, wherein said metal constitutes a central atom having coordinated thereto at least one amide ligand, with remaining non-amide ligands being independently selected from among guanidinate, amidinate and isoureate ligands.

38-47. (canceled)

48. A precursor composition comprising at least one metal precursor according to claim 1, and a solvent for the metal precursor(s).

49. The precursor composition of claim 48, wherein said solvent comprises at least one solvent species selected from among C₃-C₁₂ alkanes, C₂-C₁₂ ethers, C₆-C₁₂ aromatics, C₇-C₁₆ arylalkanes, C₁₀-C₂₅ arylcyloalkanes, and further alkyl-substituted forms of aromatic, arylalkane and arylcyloalkane species, wherein the further alkyl substituents in the case of multiple alkyl substituents may be the same as or different from one another and wherein each is independently selected from C₁-C₈ alkyl.

50-59. (canceled)

60. The method of claim 21, conducted in the presence of an oxidant selected from among nitrous oxide, oxygen, ozone, water, alcohols, and mixtures of two or more of the foregoing.

61-72. (canceled)

73. A method of forming a metal-containing film on a substrate, wherein said metal comprises a metal species selected from among zirconium, hafnium and titanium, said method comprising volatilizing a metal precursor according to claim 10, to form a precursor vapor, and contacting said precursor vapor with a substrate to form said metal-containing film thereon.
